(19) United States
(12) Patent Application Publication
(10) Pub. No.: US 2026/0215343 A1
(43) Pub. Date: Jul. 23, 2026

(54) SEMICONDUCTOR PRODUCT AND SEMICONDUCTOR DEVICE

(71) Applicant: Socionext Inc., Kanagawa (JP)

(72) Inventor: Masatoshi TSUGE, Yokohama (JP)

(21) Appl. No.: 19/569,542

(22) Filed: Mar. 17, 2026

Related U.S. Application Data
(63) Continuation of application No. PCT/JP2023/034425, filed on Sep. 22, 2023.

(51) Int. Cl. H10W 90/10; H10D 1/68; H10W 70/60; H10W 90/00

(52) U.S. Cl. CPC H10W 90/10; H10D 1/68; H10W 70/611; H10W 90/401

(57) ABSTRACT

A semiconductor product constructed with a chiplet architecture includes an interposer including an interconnect structure, a first semiconductor device including a first circuit configured to perform first signal processing and connected to a first surface of the interposer, a second semiconductor device including a second circuit configured to perform second signal processing and connected to the first surface of the interposer, and a third semiconductor device including a capacitor circuit, located adjacent to the first semiconductor device and the second semiconductor device, and connected to the first surface of the interposer, wherein the capacitor circuit is electrically connected to the first semiconductor device and the second semiconductor device via respective interconnects of a plurality of interconnects provided in the interconnect structure.

### CROSS-REFERENCE TO RELATED APPLICATION

This application is a continuation application of International Application No. PCT/JP2023/034425, filed on Sep. 22, 2023, and designated the U.S., the entire contents of which are incorporated herein by reference.

### BACKGROUND OF THE INVENTION

### 1. Field of the Invention

The disclosures herein relate to semiconductor products and semiconductor devices.

### 2. Description of the Related Art

In order to reduce power-supply noise of a semiconductor device and to operate the semiconductor device at a high speed and stably, a capacitor element may be arranged close to the semiconductor device. For example, a semiconductor chip and a capacitor chip are arranged side by side on a substrate, and pads of the semiconductor chip and those of the capacitor chip are interconnected via terminals provided on the substrate via bonding wires. Alternatively, pads of the semiconductor chip and those of the capacitor chip are connected to the substrate via bumps and are interconnected via the substrate.

When a semiconductor chip and a capacitor chip are stacked on a substrate, for example, pads of the semiconductor chip and those of the capacitor chip are interconnected by bonding wires via terminals provided on the substrate. Alternatively, pads of the semiconductor chip and those of the capacitor chip are interconnected via bumps. Further, a capacitor component having a through conductor for connecting the substrate and the semiconductor chip may be provided between the substrate and the semiconductor chip.

In what is called a 2.5-dimensional mounting technology, an interposer is arranged on a substrate, and a plurality of semiconductor chips are arranged side by side on the interposer. The plurality of semiconductor chips are interconnected via the interposer.

### CITATION LIST

### Patent Literature

[PTL 1] Japanese Laid-Open Patent Publication No. 2001-035990

[PTL 2] Japanese Laid-Open Patent Publication No. 2006-041061

[PTL 3] Japanese Laid-Open Patent Publication No. 2007-318049

[PTL 4] U.S. Patent Application Publication No. 2010/0123215

[PTL 5] U.S. Patent Application Publication No. 2022/0059452

[PTL 6] Japanese Laid-Open Patent Publication No. 2017-228647

[PTL 7] Japanese Laid-Open Patent Publication No. 2018-182027

### SUMMARY OF THE INVENTION

A semiconductor product constructed with a chiplet architecture includes an interposer including an interconnect structure, a first semiconductor device including a first circuit configured to perform first signal processing and connected to a first surface of the interposer, a second semiconductor device including a second circuit configured to perform second signal processing and connected to the first surface of the interposer, and a third semiconductor device including a capacitor circuit, located adjacent to the first semiconductor device and the second semiconductor device, and connected to the first surface of the interposer, wherein the capacitor circuit is electrically connected to the first semiconductor device and the second semiconductor device via respective interconnects of a plurality of interconnects provided in the interconnect structure.

According to the disclosed technology, in a semiconductor product in which a plurality of semiconductor devices are arranged side by side on the interposer, a capacitor for reducing noise can be arranged at an appropriate position according to a frequency band of noise while preventing an increase in cost.

### BRIEF DESCRIPTION OF THE DRAWINGS

FIG. 1 is a plan view illustrating a first embodiment of a semiconductor package;

FIG. 2 is a cross-sectional view illustrating an example of a cross section taken along an X-X′ line of the semiconductor package of FIG. 1;

FIG. 3 is a cross-sectional view illustrating another example of a cross section along the X-X′ line of the semiconductor package of FIG. 1;

FIG. 4 is a cross-sectional view illustrating an example of a cross section of another semiconductor package;

FIG. 5 is a plan view illustrating an example of a modification of a related semiconductor package;

FIG. 6 is a plan view illustrating another example of a modification of a related semiconductor package;

FIG. 7 is a plan view illustrating a second embodiment of a semiconductor package;

FIG. 8 is a plan view illustrating one embodiment of a capacitor chiplet;

FIG. 9 is a plan view illustrating an example of connecting the capacitor chiplet of FIG. 8 to a plurality of chiplets; and

FIG. 10 is a drawing illustrating an example of connection of power supply lines and ground lines between the capacitor chiplet and the plurality of chiplets of FIG. 9.

### DESCRIPTION OF THE PREFERRED EMBODIMENTS

In the following, embodiments of the present invention will be described with reference to the accompanying drawings. Hereinafter, reference numerals indicating signals are also used as reference numerals indicating signal lines or signal terminals. Reference numerals indicating power supplies are also used as reference numerals indicating power supply lines or power supply terminals to which power supply potentials are supplied, or reference numerals indicating ground lines or ground terminals to which ground potentials are supplied.

In a semiconductor product in which a plurality of semiconductor devices are arranged side by side on an interposer, a method for arranging a capacitor for reducing noise at an appropriate position according to a frequency band of noise while preventing an increase in cost has not been proposed.

An object of the present invention is to arrange a capacitor for reducing noise at an appropriate position according to a frequency band of noise while preventing an increase in cost in a semiconductor product in which a plurality of semiconductor devices are arranged side by side on the interposer.

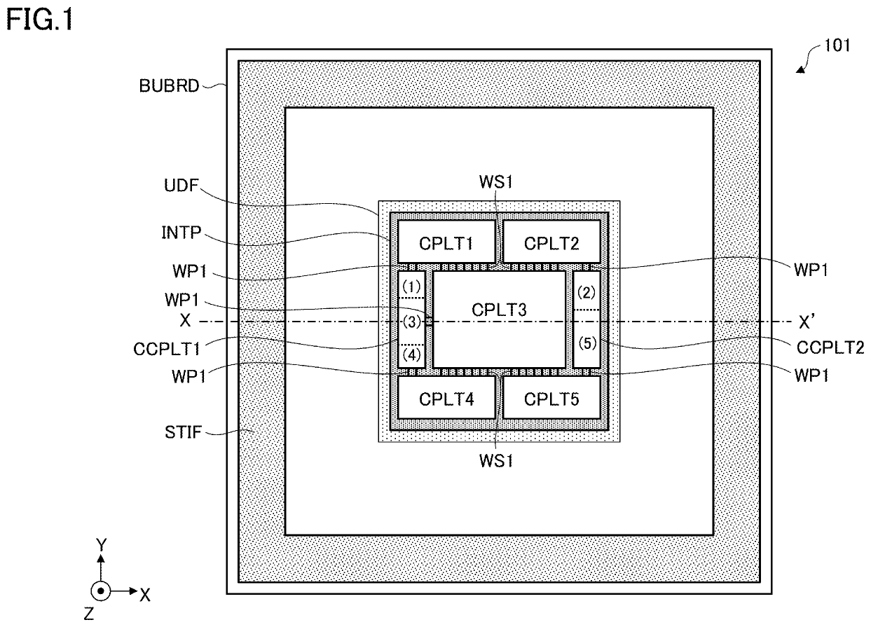

FIG. 1 illustrates a first embodiment of a semiconductor package. A semiconductor package 101 shown in FIG. 1 includes a build-up board BUBRD and an interposer INTP and a stiffener STIF arranged on the build-up board BUBRD. The semiconductor package 101 also includes chiplets CPLT1, CPLT2, CPLT3, CPLT4, and CPLT5 arranged on the interposer INTP, and capacitor chiplets CCPLT1 and CCPLT2.

In the following, when the chiplets CPLT1-CPLT5 are described without distinction, they are also referred to simply as chiplets CPLT. When the capacitor chiplets CCPLT1 and CCPLT2 are described without distinction, they are also referred to simply as capacitor chiplets CCPLT.

Each of the chiplets CPLT has a circuit for performing signal processing. The capacitor chiplets CCPLT1 and CCPLT2 include a capacitor circuit, are placed in a vacant area where the chiplets CPLT are not placed on the interposer INTP, and include a plurality of electrically separated capacitor elements. By placing the capacitor chiplets CCPLT1 and CCPLT2 in the vacant area on the interposer INTP, steps between the chiplets CPLT on the interposer INTP can be eliminated, and a planar surface can be achieved. Accordingly, for example, the surface of a molding material disposed on the build-up board BUBRD to cover the chiplets CPLT and the capacitor chiplets CCPLT can be made planar.

The semiconductor package 101 is an example of a semiconductor product constructed with a chiplet architecture. The build-up board BUBRD is an example of a package substrate. For example, each chiplet CPLT is an example of a first semiconductor device including a first circuit for performing first signal processing or a second semiconductor device including a second circuit for performing second signal processing. Each capacitor chiplet CCPLT is an example of a third semiconductor device adjacent to the first semiconductor device and the second semiconductor device.

An underfill UDF is filled between the build-up board BUBRD and the interposer INTP. The stiffener STIF is annularly attached to the outer peripheral portion of the build-up board BUBRD and functions as a ring for preventing the build-up board BUBRD from warping.

Chiplets CPLT1 and CPLT2 are disposed adjacent to each other in an X-direction on the interposer INTP, and capacitor chiplets CCPLT1, CPLT3, and CCPLT2 are disposed adjacent to each other in the X-direction. Chiplets CPLT4 and CPLT5 are disposed adjacent to each other in the X-direction on the interposer INTP. The capacitor chiplets CCPLT1 and CPLT3 are disposed adjacent to the chiplets CPLT1 and CPLT4 in a Y-direction. The chiplet CPLT3 and the capacitor chiplet CCPLT2 are adjacent to the chiplets CPLT2 and CPLT5 in the Y-direction.

Solid lines shown between the chiplets CPLT1, CPLT2, CPLT4, and CPLT5 and the chiplet CPLT3 indicate signal lines WS1 provided in the interposer INTP. The signal lines WS1 are provided in an interconnect layer in the interposer INTP. The number of signal lines WS1 is not limited to FIG. 1. Solid lines shown between the chiplets CPLT1, CPLT3, and CPLT4 and the capacitor chiplet CCPLT1 indicate power supply lines WP1. Solid lines shown between the chiplets CPLT2 and CPLT5 and the capacitor chiplet CCPLT2 indicate power supply lines WP1.

Since each of the chiplets CPLT and each of the capacitor chiplets CCPLT is connected via the interposer INTP, interconnection resistance can be reduced as compared with the case of connecting via a build-up board BUBRD.

The power supply line WP1 is provided in the interconnect layer in the interposer INTP and includes, for example, a power supply line and a ground line. That is, a capacitor element of a capacitor circuit included in each capacitor chiplet CCPLT is electrically connected to the chiplet CPLT via the power supply line and the ground line. The signal line WS1 is an example of an interconnect that electrically connects the chiplets CPLT. The power supply line WP1 is an example of an interconnect for electrically connecting the chiplet CPLT and the capacitor chiplet CCPLT.

Each capacitor chiplet CCPLT has only a capacitor circuit including a capacitor element connected to the power supply line and the ground line. Since each capacitor chiplet CCPLT is connected only to the power supply line and the ground line and is not connected to the signal line, it does not include a processing circuit such as a logic circuit or an analog circuit that receives an input signal and operates to output an output signal. That is, each capacitor chiplet CCPLT includes only a capacitor circuit that is a passive element and does not include an active circuit that performs signal processing. In other words, each capacitor chiplet CCPLT does not have a function of independently performing active signal processing for generating an output signal with respect to an input signal. In addition to the above-described capacitor elements, the capacitor circuit may include other passive elements such as, for example, an Electrostatic Discharge (ESD) protection element.

Reference numerals (1) to (5) shown in capacitor chiplets CCPLT1 and CCPLT2 are examples of capacitor circuit blocks having capacitor elements. Reference numerals (1), (3), and (4) shown in capacitor chiplet CCPLT1 indicate capacitor circuit blocks including capacitor elements connected to chiplets CPLT1, CPLT3, and CPLT4, respectively, via the power supply lines WP1. Reference numerals (2) and (5) shown in capacitor chiplet CCPLT2 indicate capacitor circuit blocks including capacitor elements connected to chiplets CPLT2 and CPLT5, respectively, via the power supply lines WP1. Each of the capacitor elements functions as a decoupling capacitor for a circuit in the chiplet CPLT that is connected via the power supply line WP1.

By sharing each capacitor chiplet CCPLT arranged in a free area with a plurality of chiplets CPLT, a capacitor circuit of an appropriate size located near each chiplet CPLT can be connected to each chiplet CPLT. As a result, power-supply noise can be suitably reduced in accordance with the operating frequency and function of each chiplet CPLT.

At least one of the chiplets CPLT is fabricated according to a process rule having finer processing accuracy which enables formation of finer feature size than a process used to fabricate the capacitor chiplet CCPLT. For example, the capacitor chiplet CCPLT can be fabricated using a fabrication process of an earlier generation than the fabrication process used for fabricating the chiplet CPLT. Therefore, the fabrication cost of the capacitor chiplet CCPLT can be lower than that of the chiplet CPLT. In addition, compared with the case where a capacitor element is incorporated inside the chiplet CPLT instead of using a capacitor chiplet CCPLT, the chip size of the chiplet CPLT can be reduced and the yield (i.e., the proportion of non-defective chiplets CPLT) can be improved; thus, the fabrication cost of the chiplet CPLT and the semiconductor package 101 can be reduced.

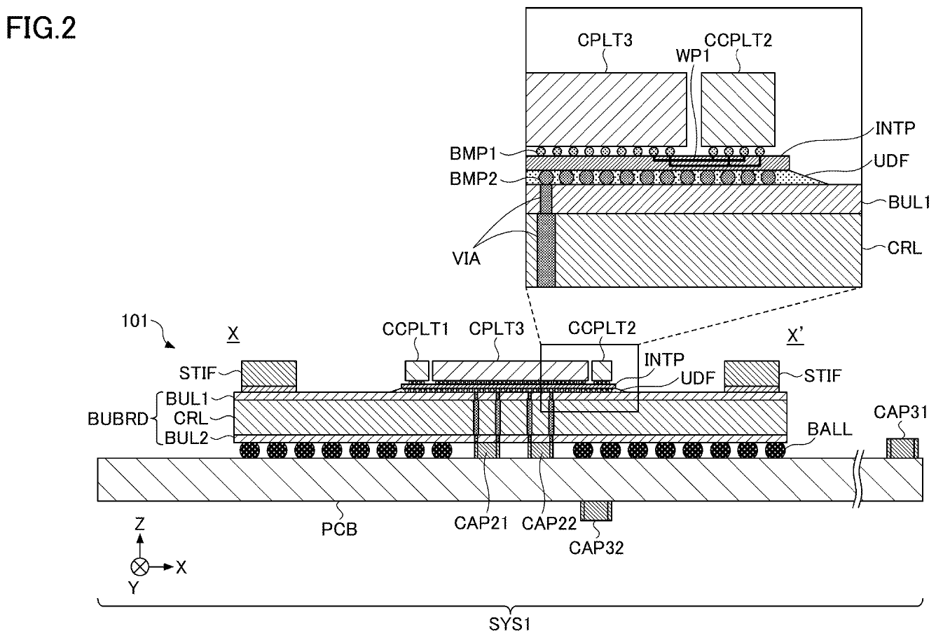

FIG. 2 illustrates an example of a cross section taken along an X-X′ line of the semiconductor package 101 of FIG. 1. FIG. 2 shows an example of a system SYS1 including the semiconductor package 101 connected to a printed circuit board PCB via LSI (Large-Scale Integration) balls BALL.

In the interposer INTP, the surface on the side of the chiplet CPLT and the capacitor chiplet CCPLT is an example of a first surface, and the surface on the side of the build-up board BUBRD is an example of a second surface. In the build-up board BUBRD, the surface on the side of the interposer INTP is an example of a third surface, and the surface on the side of the printed circuit board PCB is an example of a fourth surface.

Hereinafter, in the interposer INTP, the build-up board BUBRD, and the printed circuit board PCB, the surface on the side of the chiplet CPLT and the capacitor chiplet CCPLT may be referred to as the front surface. In the interposer INTP, the build-up board BUBRD, and the printed circuit board PCB, the surface opposite the chiplet CPLT and the capacitor chiplet CCPLT may be referred to as the back surface.

Each of the respective chiplets CPLT and the capacitor chiplets CCPLT are interconnected with the interposer INTP via, for example, bumps BMP1. For example, the bumps BMP1 are micro-bumps or the like and are arranged at a pitch of several tens of microns. The power supply terminal and the ground terminal of the chiplet CPLT connected to the bumps BMP1 are respectively connected to the power supply terminal and the ground terminal of the capacitor chiplet CCPLT via a power supply line WP1 formed in the interposer INTP. The bumps BMP1 represent an example of either a first bump or a second bump.

The signal terminal of each chiplet CPLT is connected to the signal terminal of another chiplet CPLT or bumps BMP2 via a signal line WS1 (not shown) formed in the interposer INTP (FIG. 1). The power supply terminal and the ground terminal of each chiplet CPLT are respectively connected to the bumps BMP2 via a power supply line WP1 (not shown) formed in the interposer INTP.

For example, the bumps BMP2 are C4 (Controlled Collapse Chip Connection) bumps, Cu pillars, or the like, and are arranged at a pitch of approximately 150 to 200 microns. The bumps BMP2 represent an example of a third bump.

The build-up board BUBRD has a build-up layer BUL1 provided on the interposer INTP side, a build-up layer BUL2 provided on the printed circuit board PCB side, and a core layer CRL provided between the build-up layers BUL1 and BUL2. The build-up layers BUL1 and BUL2 have one or more wiring layers. Although not particularly limited, the thickness of the build-up board BUBRD is, for example, approximately 0.5 mm to 2 mm.

For example, the bumps BMP2 electrically connected to the power supply terminal and the ground terminal of the chiplet CPLT are connected to vias VIA extending through the build-up layers BUL1 and BUL2 and the core layer CRL of the build-up board BUBRD. A pair of vias VIA respectively connected to the power supply terminal and the ground terminal are connected to a pair of terminals of a capacitor CAP21 or a capacitor CAP22 such as a ceramic capacitor disposed on the back surface of the build-up board BUBRD.

In the example shown in FIG. 2, a capacitor CAP31 connected to a power supply line and a ground line is disposed on the front surface of the printed circuit board PCB. A capacitor CAP32 connected to a power supply line and a ground line is disposed on the back surface of the printed circuit board PCB. The capacitors CAP31 and CAP32 are ceramic capacitors or the like. The capacitors CAP31 and CAP32 are connected to a power supply line, a ground line, and an LSI ball BALL, and are connected to either a power supply terminal or a ground terminal of the chiplet CPLT, via wiring lines of a wiring layer provided on the printed circuit board PCB,. The LSI ball BALL is an example of an external connection terminal.

For example, the capacitor chiplet CCPLT functions as a decoupling capacitor for reducing power-supply noise in a GHz band, which is a frequency band from 1 GHz to several tens of GHz. For example, the capacitors CAP21 and CAP22 function as decoupling capacitors for reducing power-supply noise in the frequency band from several tens of MHz to several hundreds of MHz. The distance between the capacitor chiplet CCPLT1 and the chiplet CPLT3, and the distance between the capacitor chiplet CCPLT2 and the chiplet CPLT3 are shorter than the distance between the capacitors CAP21 and CAP22 and the chiplet CPLT3.

For example, the capacitors CAP31 and CAP32 function as decoupling capacitors for reducing power-supply noise in a frequency band from several MHz to several tens of MHz. The capacitors CAP21, CAP22, CAP31, and CAP32 are examples of capacitor devices.

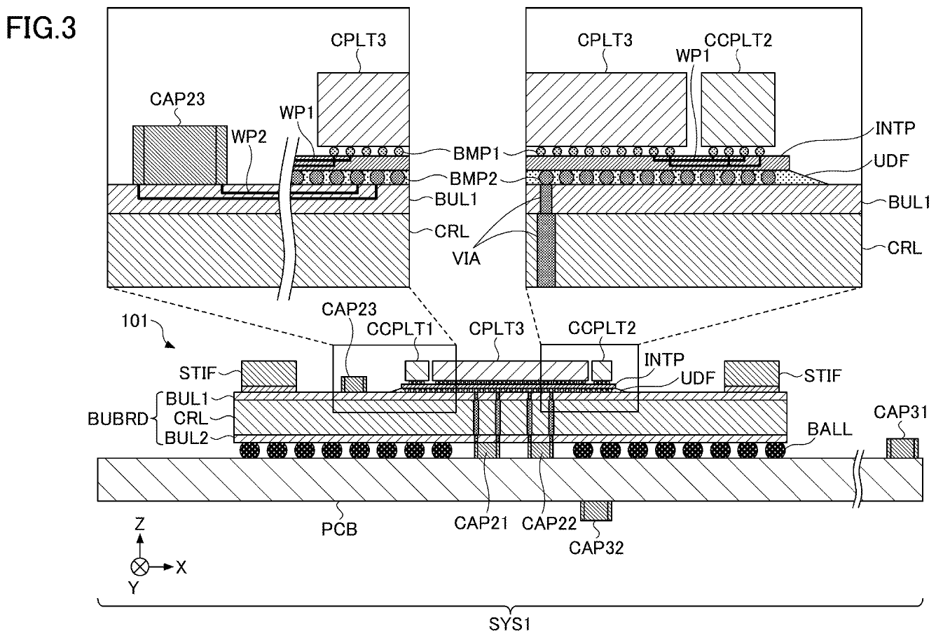

FIG. 3 illustrates another example of a cross section along the X-X′ line of the semiconductor package 101 of FIG. 1. The same elements as those in FIG. 2 are denoted by the same reference numerals and detailed description thereof is omitted. The configuration and structure of the semiconductor package 101 of FIG. 3 are the same as those of the semiconductor package 101 of FIG. 2 except that a capacitor CAP23, such as a ceramic capacitor, is disposed on the build-up board BUBRD. For example, the capacitor CAP23 is a ceramic capacitor or the like, and functions as a decoupling capacitor for reducing power-supply noise in a frequency band of several hundred MHz. The capacitor CAP23 is an example of a capacitor device.

For example, the capacitor CAP23 is connected to the power supply terminal and the ground terminal of the chiplet CPLT3 via the power supply line WP2, the bumps BMP2, the interposer INTP, and the bumps BMP1 provided in the build-up layer BUL1. Since the capacitor CAP23 disposed on the surface of the build-up board BUBRD is disposed avoiding the underfill UDF, it cannot be disposed closer to the interposer INTP than the underfill UDF. Conversely, the capacitor chiplets CCPLT1 and CCPLT2 are disposed on the interposer INTP.

Therefore, the distance between the capacitor CAP23 and the chiplet CPLT3 is longer than the distance between the capacitor chiplet CCPLT1 and the chiplet CPLT3 and the distance between the capacitor chiplet CCPLT2 and the chiplet CPLT3. In other words, the lengths of the power supply line and the ground line connecting the capacitor CAP23 and the chiplet CPLT3 are longer than the lengths of the power supply line and the ground line connecting the capacitor chiplet CCPLT1 and the chiplet CPLT3 and the lengths of the power supply line and the ground line connecting the capacitor chiplet CCPLT2 and the chiplet CPLT3. Therefore, it is difficult to make the capacitor CAP23 disposed on the surface of the build-up board BUBRD function as a decoupling capacitor for reducing power-supply noise in the GHz band.

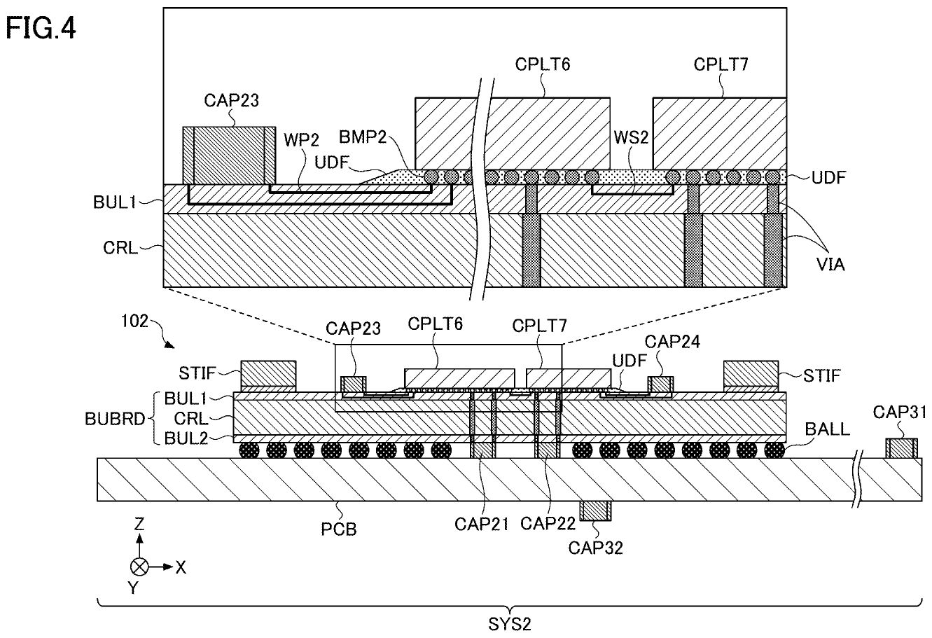

FIG. 4 illustrates an example of a cross section of another semiconductor package. The same elements as those in FIG. 2 are denoted by the same reference numerals, and a detailed description thereof is omitted. A semiconductor package 102 of FIG. 4 has the chiplets CPLT6 and CPLT7, but does not have the capacitor chiplets CCPLT1 and CCPLT2 and the interposer INTP of FIG. 2. The chiplets CPLT6 and CPLT7 are interconnected via signal lines WS2 and the bumps BMP2 provided in the build-up layer BUL1. The printed circuit board PCB to which the build-up board BUBRD is connected operates as a system SYS2.

The capacitor CAP23 disposed on the build-up board BUBRD is connected to the power supply terminal and the ground terminal of the chiplet CPLT6 via the power supply line WP2 and the bumps BMP2 in the build-up layer BUL1. Similarly, a capacitor CAP24 disposed on the build-up board BUBRD is connected to the power supply terminal and the ground terminal of the chiplet CPLT7 via the power supply line WP2 and the bumps BMP2 in the build-up layer BUL1. Other configurations and structures of the semiconductor package 102 are the same as those of the semiconductor package 101 in FIG. 2.

The semiconductor package 102 does not have the interposer INTP and the capacitor chiplets CCPLT1 and CCPLT2 including the capacitor circuit disposed on the interposer INTP. Therefore, for example, decoupling capacitors for reducing power-supply noise in the GHz band are mounted inside the chiplets CPLT6 and CPLT7. In this case, as compared with a case in which capacitor chiplets CCPLT1 and CCPLT2 are disposed on the interposer INTP, the chip size of the chiplets CPLT6 and CPLT7 becomes larger and the yield is reduced, resulting in increased fabrication costs of the chiplets CPLT and the semiconductor package 102.

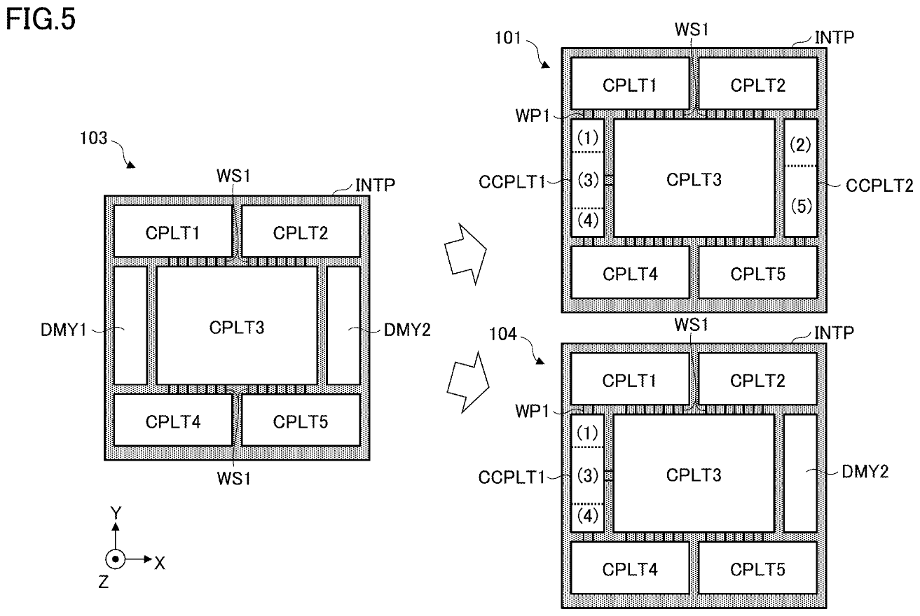

FIG. 5 illustrates an example of a modification of a related semiconductor package. In FIG. 5, only the interposer INTP and elements arranged on the interposer INTP are shown for simplicity of explanation. The same elements as those in FIG. 1 are denoted by the same reference numerals, and detailed explanation is omitted.

A related semiconductor package 103 has chiplets CPLT1 to CPLT5 and dummy chiplets DMY1 and DMY2 arranged on the interposer INTP. The dummy chiplets DMY1 and DMY2 are examples of dummy semiconductor devices. The dummy chiplets DMY1 and DMY2 are placed in a vacant area on the interposer INTP in order to eliminate steps on the interposer INTP. For example, adjacent chiplets CPLT are connected by a signal line WS1.

The dummy chiplets DMY1 and DMY2 have terminals that are mechanically or electrically connected to the interposer INTP via the bumps BMP1 (not shown), but do not perform any signal processing. For example, the dummy chiplets DMY1 and DMY2 may have dummy circuits, but do not input or output signals to or from the outside of the dummy chiplets DMY1 and DMY2.

The semiconductor package 101 is formed by replacing the dummy chiplets DMY1 and DMY2 of the semiconductor package 103 with capacitor chiplets CCPLT1 and CCPLT2 including capacitor circuits. The semiconductor package 101 is an example of a semiconductor product configured by a chiplet architecture. By replacing the dummy chiplets DMY1 and DMY2 with capacitor chiplets CCPLT1 and CCPLT2, a capacitor circuit of an appropriate size can be connected to each of the chiplets CPLT1 to CPLT5 without forming decoupling capacitors in the chiplets CPLT1 to CPLT5. As a result, power-supply noise in the GHz band can be reduced.

In addition, because regions for forming decoupling capacitors in chiplets CPLT1 to CPLT5 can be replaced with regions for forming active elements such as transistors, an increase in chip size can be prevented and the processing capability of chiplets CPLT1 to CPLT5 can be improved. Further, by replacing the dummy chiplets DMY1 and DMY2 with the capacitor chiplets CCPLT1 and CCPLT2, the upper surfaces of the chiplets CPLT and the capacitor chiplets CCPLT can be kept planar. Accordingly, the surface of the molding material can be made planar.

A semiconductor package 104 is formed by replacing the dummy chiplet DMY1 of the semiconductor package 103 with the capacitor chiplet CCPLT1 including a capacitor circuit. The semiconductor package 104 is an example of a semiconductor product configured by a chiplet architecture.

For example, the semiconductor package 104 is an example of a configuration in which the operating frequencies of the chiplets CPLT2 and CPLT5 are lower than the operating frequencies of the other chiplets CPLT1, CPLT3, and CPLT4, and power-supply noise in the GHz band is hardly generated. By replacing the dummy chiplet DMY1 with the capacitor chiplet CCPLT1, a capacitor circuit of an appropriate size can be connected to each of the chiplets CPLT1, CPLT3, and CPLT4. As a result, power-supply noise in the GHz band can be reduced in each of the chiplets CPLT1, CPLT3, and CPLT4. Conversely, since noise generation can be reduced in chiplets CPLT2 and CPLT5 without placing a capacitor chiplet CCPLT2, the dummy chiplet DMY2 remains disposed on the interposer INTP.

When there is a vacant area on the interposer INTP where the chiplet CPLT and the capacitor chiplet CCPLT are not placed, by placing the dummy chiplet DMY in the vacant area, the surface of the molding material can be made planar.

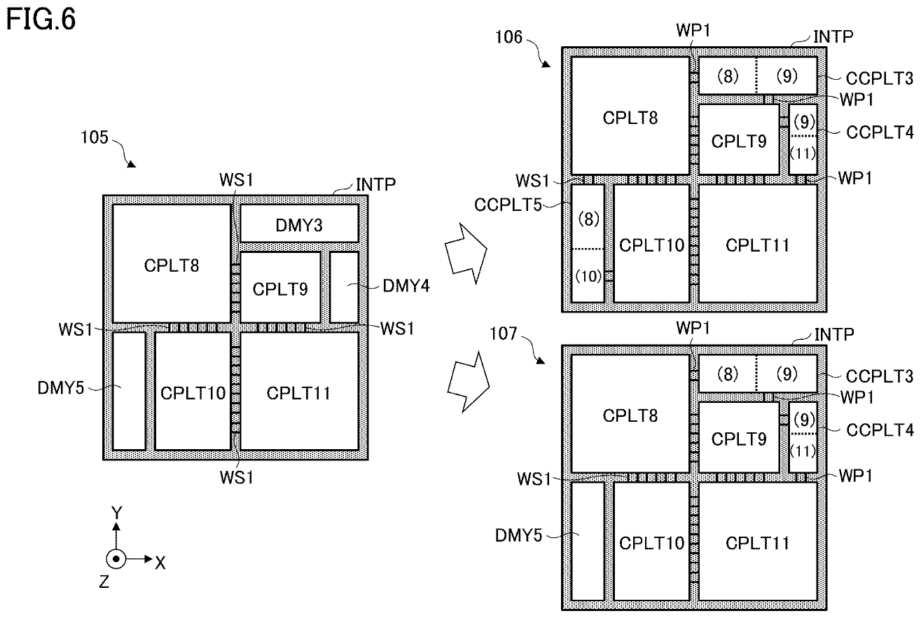

FIG. 6 illustrates another example of a modification of a related semiconductor package In FIG. 5, only the interposer INTP and elements placed on the interposer INTP are shown for simplicity of explanation. A related semiconductor package 105 has chiplets CPLT8, CPLT9, CPLT10, and CPLT11 arranged on the interposer INTP and dummy chiplets DMY3, DMY4, and DMY5. For example, as in the semiconductor package 103 of FIG. 5, adjacent chiplets CPLT are connected by the signal lines WS1.

A semiconductor package 106 is formed by replacing dummy chiplets DMY3 to DMY5 of the semiconductor package 105 with capacitor chiplets CCPLT3 to CCPLT5 including capacitor circuits. The capacitor chiplets CCPLT3 to CCPLT5 have different sizes and different sizes of capacitor circuits included therein. The semiconductor package 106 is an example of a semiconductor product configured by a chiplet architecture.

Hereinafter, when the chiplets CPLT8 to CPLT11 are described without distinction, they are also referred to simply as chiplets CPLT. When the capacitor chiplets CCPLT3 to CCPLT5 are described without distinction, they are also referred to simply as capacitor chiplets CCPLT. Each of the capacitor elements of the capacitor circuits of the capacitor chiplets CCPLT3 to CCPLT5 functions as a decoupling capacitor for the circuit in the chiplet CPLT that is connected via the power supply line WP1.

Each of the chiplets CPLT is an example of a first semiconductor device having a first circuit for performing first signal processing or a second semiconductor device having a second circuit for performing second signal processing. Each of the capacitor chiplets CCPLT is an example of a third semiconductor device adjacent to the first semiconductor device and the second semiconductor device. The dummy chiplets DMY3 to DMY5 are examples of dummy semiconductor devices.

Reference numerals (8) to (11) shown in capacitor chiplets CCPLT3 and CCPLT4 are examples of capacitor circuit blocks having capacitor elements. Reference numerals (8) and (9) shown in capacitor chiplet CCPLT3 indicate capacitor circuit blocks including capacitor elements connected to chiplets CPLT8 and CPLT9, respectively, via power supply lines WP1. Reference numerals (9) and (11) shown in capacitor chiplet CCPLT4 indicate capacitor circuit blocks including capacitor elements connected to chiplets CPLT9 and CPLT11, respectively, via power supply lines WP1. Reference numerals (8) and (10) shown in capacitor chiplet CCPLT5 indicate capacitor circuit blocks including capacitor elements connected to chiplets CPLT8 and CPLT10, respectively, via power supply lines WP1.

For example, in the semiconductor package 106, chiplet CPLT8 can be connected to a plurality of capacitor chiplets CCPLT3 and CCPLT5. Similarly, chiplet CPLT9 can be connected to a plurality of capacitor chiplets CCPLT3 and CCPLT4.

Thus, even when capacitor chiplets CCPLT of various different sizes are formed in a region where chiplets CPLT are not formed on interposer INTP, capacitor circuits of appropriate sizes can be connected to respective chiplets CPLT8 and CPLT9. As a result, power-supply noise in the GHz band can be appropriately reduced according to the operating frequency, function, and the like of respective chiplets CPLT8 and CPLT9.

A semiconductor package 107 can be formed by replacing the dummy chiplets DMY3 and DMY4 of the semiconductor package 105 with capacitor chiplets CCPLT3 and CCPLT4 including capacitor circuits. The semiconductor package 107 is an example of a semiconductor product configured by a chiplet architecture.

Similar to the semiconductor package 104 in FIG. 5, the semiconductor package 107 is an example of a configuration in which the operating frequency of the chiplet CPLT10 is lower than the operating frequency of the other chiplets CPLT8, CPLT9, and CPLT11, so that power-supply noise in the GHz band hardly occurs. By replacing the dummy chiplets DMY3 and DMY4 with capacitor chiplets CCPLT3 and CCPLT4, a capacitor circuit of an appropriate size can be connected to each of the chiplets CPLT8, CPLT9, and CPLT11. As a result, power-supply noise in the GHz band can be reduced in each of the chiplets CPLT8, CPLT9, and CPLT11. Conversely, since noise generation can be reduced in the chiplet CPLT10 even if the capacitor chiplet CCPLT5 is not arranged, the dummy chiplet DMY5 is arranged as it is.

As described above, in the first embodiment of the semiconductor package, the capacitor chiplets CCPLT including only capacitor circuits are arranged adjacent to a plurality of chiplets CPLT on the interposer INTP. The chiplets CPLT are respectively connected to the capacitor circuit blocks in the capacitor chiplet CCPLT via the respective power supply lines and the ground lines in the interposer INTP. As a result, the capacitor chiplet CCPLT arranged in a region where the chiplet CPLT is not arranged on the interposer INTP can function as a decoupling capacitor for the plurality of chiplets CPLT.

In addition, since the chiplet CPLT and the capacitor chiplet CCPLT are connected via the interposer INTP, the interconnection resistance can be reduced as compared with the case where they are connected via the build-up board BUBRD. Since the capacitor chiplet CCPLT can be arranged near the chiplet CPLT, the capacitor chiplet CCPLT can function as a decoupling capacitor for reducing power-supply noise in the GHz band.

Since the capacitor chiplet CCPLT including only the capacitor circuit can be fabricated using, for example, a fabrication process of an earlier generation than the fabrication process for fabricating the chiplet CPLT, the fabrication cost can be lower than that of the chiplet CPLT. Furthermore, since a capacitor for decoupling does not need to be included in the chiplet CPLT, the chip size of the chiplet CPLT can be reduced, and the yield of the chiplet CPLT can be improved, thus the fabrication cost of the chiplet CPLT and the semiconductor packages 101, 104, 106, and 107 can be reduced. As a result, the semiconductor packages 101, 104, 106, and 107 having a decoupling capacitor for reducing power-supply noise in the GHz band can be formed at reduced fabrication cost.

For example, the capacitor chiplet CCPLT is disposed, instead of a dummy chiplet DMY, in a vacant area on the interposer INTP where no chiplet CPLT is arranged and which is originally intended for placement of the dummy chiplet DMY. As a result, steps on the interposer INTP are reduced by the capacitor chiplet CCPLT, thereby making the surface of the molding material planar, while allowing the capacitor chiplet CCPLT to function as a decoupling capacitor for reducing power-supply noise in the GHz band.

By using the capacitor chiplet CCPLT disposed in the vacant area in common with a plurality of chiplets CPLT, a capacitor circuit of an appropriate size disposed near each chiplet CPLT can be connected to each chiplet CPLT. As a result, power-supply noise can be suitably reduced according to the operating frequency, function, or the like of each chiplet CPLT.

When there is a vacant area where the chiplet CPLT and the capacitor chiplet CCPLT are not placed on the interposer INTP, by placing the dummy chiplet DMY in the vacant area, the surface of the molding material can be made planar.

A capacitor CAP connected to a power supply line VDD and a ground line VSS is disposed on either or both of the build-up board BUBRD to which the interposer INTP is connected and the printed circuit board PCB to which the build-up board BUBRD is connected. Accordingly, power-supply noise can be reduced over a plurality of frequency bands by the capacitor chiplet CCPLT together with the capacitor CAP.

As described above, in a semiconductor package in which a plurality of chiplets CPLT are arranged side by side, the capacitor chiplets CCPLT and the capacitor CAP can be arranged at appropriate positions according to the frequency bands of noise while preventing an increase in cost. As a result, the semiconductor packages 101, 104, 106, and 107 that can appropriately reduce power-supply noise in each frequency band can be formed.

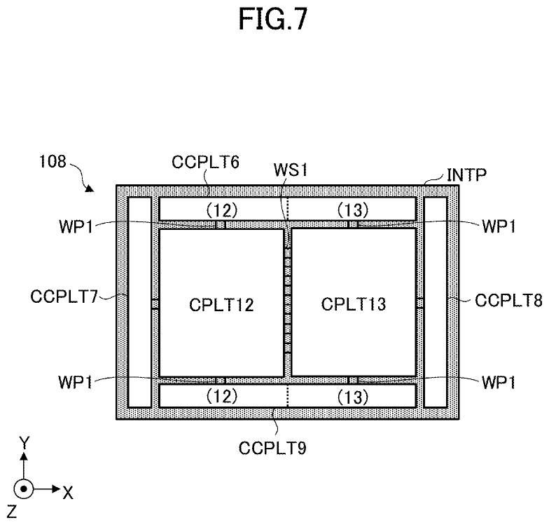

FIG. 7 illustrates a second embodiment of a semiconductor package. Elements similar to those in the first embodiment are denoted by the same reference numerals, and detailed description thereof is omitted. Also in FIG. 7, only the interposer INTP and elements arranged on the interposer INTP are shown for simplicity of description.

As in FIGS. 1 and 2, a semiconductor package 108 shown in FIG. 7 has a build-up board BUBRD (not shown) on which the interposer INTP is arranged. The build-up board BUBRD is mounted on a printed circuit board PCB (not shown), and the semiconductor package 108 operates as a system. The semiconductor package 108 is an example of a semiconductor product configured by a chiplet architecture.

In the semiconductor package 108 shown in FIG. 7, the regions in which chiplets CPLT12 and CPLT13 are disposed are rectangular and have no steps for placing a dummy chiplet DMY. Therefore, when the capacitor chiplets CCPLT6 to CCPLT9 including a capacitor circuit functioning as a decoupling capacitor are required, the capacitor chiplets CCPLT6 to CCPLT9 are arranged around the chiplets CPLT12 and CPLT13. A solid line shown between the chiplets CPLT12 and CPLT13 indicates a signal line WS1.

Hereinafter, when the chiplets CPLT12 and CPLT13 are described without distinction, they are also referred to simply as chiplets CPLT. When the capacitor chiplets CCPLT6 to CCPLT9 are described without distinction, they are also referred to simply as capacitor chiplets CCPLT.

Each of the chiplets CPLT is an example of a first semiconductor device having a first circuit for performing first signal processing or a second semiconductor device having a second circuit for performing second signal processing. Each capacitor chiplet CCPLT is an example of a third semiconductor device adjacent to the first semiconductor device and the second semiconductor device.

Capacitor chiplet CCPLT6 is connected to chiplets CPLT12 and CPLT13. Capacitor chiplet CCPLT7 is connected to chiplet CPLT12. Capacitor chiplet CCPLT8 is connected to chiplet CPLT13. Capacitor chiplet CCPLT9 is connected to chiplets CPLT12 and CPLT13.

As in FIGS. 5 and 6, reference numerals (12) and (13) in capacitor chiplets CCPLT6 and CCPLT9 are examples of capacitor circuit blocks having capacitor elements, and indicate capacitor circuit blocks including capacitor elements connected to chiplets CPLT12 and CPLT13 respectively via power supply line WP1.

When there are no steps for disposing dummy chiplet DMY and a decoupling capacitor for reducing power-supply noise in the GHz band is required, capacitor elements may be formed in chiplets CPLT12 and CPLT13. However, when a capacitor element is formed in the chiplets CPLT12 and CPLT13 fabricated according to a process rule having fine processing accuracy which enables formation of the feature size, the chip size increases, the yield decreases, and as a result, the chip cost increases.

Therefore, in the semiconductor package 108, capacitor chiplets CCPLT6 to CCPLT9 are arranged on the interposer INTP separately from the chiplets CPLT12 and CPLT13. At this time, by arranging the capacitor chiplets CCPLT6 to CCPLT9 around the chiplets CPLT12 and CPLT13 in plan view, the propagation delay time of signals between the chiplets CPLT12 and CPLT13 can be minimized. By arranging the capacitor chiplets CCPLT6 to CCPLT9 around the chiplets CPLT12 and CPLT13 in plan view, the size of the interposer INTP increases, but since the capacitor chiplets CCPLT can be fabricated using, for example, a fabrication process of an earlier generation than the fabrication process used for fabricating the chiplets CPLT, the fabrication cost can be lower than that of the chiplets CPLT, and therefore, the increase in the total cost of the semiconductor package 108 can be prevented.

As described above, in the semiconductor package of the second embodiment, the same effect as that of the semiconductor package of the first embodiment can be obtained. For example, the capacitor chiplets CCPLT which can be fabricated using a fabrication process which is a generation older than the chiplets CPLT can be arranged on the interposer INTP. Therefore, the capacitor chiplets CCPLT can be arranged near the chiplets CPLT with reduced fabrication cost, and the capacitor chiplets CCPLT can function as a decoupling capacitor for reducing power-supply noise in the GHz band.

Further, in the second embodiment of the semiconductor package, when there are no steps for disposing the dummy chiplet DMY among the plurality of chiplets CPLT disposed on the interposer INTP, the capacitor chiplet CCPLT is disposed around the chiplets CPLT. As a result, an increase in the total cost of the semiconductor package 108 can be prevented as compared with the case where a capacitor element is formed in the chiplets CPLT while reducing the generation of power-supply noise in the GHz band.

As described above, in the semiconductor package 108 in which the plurality of chiplets CPLT are disposed side by side, the capacitor chiplet CCPLT and the capacitor CAP (not shown) can be disposed at appropriate positions according to the frequency band of the noise while preventing an increase in the cost. As a result, power-supply noise in each frequency band can be reduced appropriately.

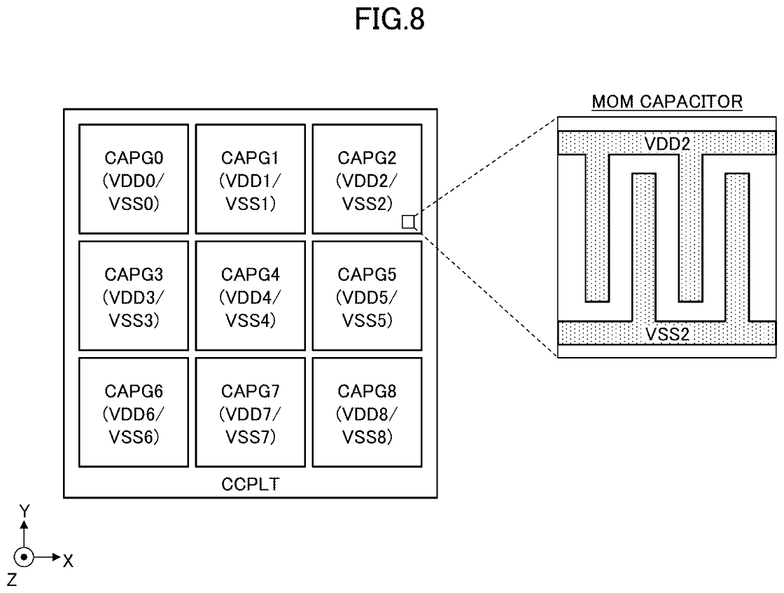

FIG. 8 illustrates one embodiment of a capacitor chiplet. The capacitor chiplet CCPLT shown in FIG. 8 is an example of a semiconductor device and has a capacitor circuit including nine capacitor groups CAPG0 to CAPG8. That is, the capacitor circuit of the capacitor chiplet CCPLT includes nine capacitor groups CAPG0 to CAPG8, and the capacitor groups CAPG0 to CAPG8 are examples of capacitor circuit blocks having capacitor elements. Each capacitor group CAPG0 to CAPG8 has only a capacitor circuit including a capacitor element connected only to a power supply line and a ground line, as in the capacitor chiplet CPLT shown in FIG. 1 and the like. Each of the capacitor groups CAPG0 to CAPG8 is connected only to the power supply line and the ground line, and is not connected to the signal line, and therefore does not include a processing circuit such as a logic circuit or an analog circuit that receives an input signal and operates to output an output signal. That is, each of the capacitor groups CAPG0 to CAPG8 includes only a capacitor circuit that is a passive element, and does not include an active circuit that performs signal processing. In other words, each of the capacitor groups CAPG0 to CAPG8 does not have a function of independently performing active signal processing for generating an output signal with respect to an input signal. In addition to the above-described capacitor elements, the capacitor circuit may include other passive elements such as an electrostatic discharge (ESD) protection element, for example.

Hereinafter, when the capacitor groups CAPG0 to CAPG8 are described without distinction, they are also referred to simply as capacitor groups CAPG. Each of the capacitor groups CAPG0 to CAPG8 has independent power supply terminals VDD0 to VDD8 and ground terminals VSS0 to VSS8.

Each of the capacitor groups CAPG has, for example, an MOM (Metal-Oxide-Metal) capacitor having a pair of comb-shaped counter electrodes, one of which is electrically connected to the power supply line VDD and the other of which is electrically connected to the ground line VSS. The MOM capacitor is an example of a capacitor element. The MOM capacitors may be formed in a plurality of wiring layers. In this case, by alternating the patterns of the power supply lines VDD and the ground lines VSS in adjacent wiring layers, a capacitor can also be formed between the wiring layers. Further, each capacitor group CAPG may be formed by a gate capacitor of a MIM (Metal-Insulator-Metal) capacitor or a transistor, or may be a combination of a gate capacitor of a MOM capacitor, a MIM capacitor, and a transistor.

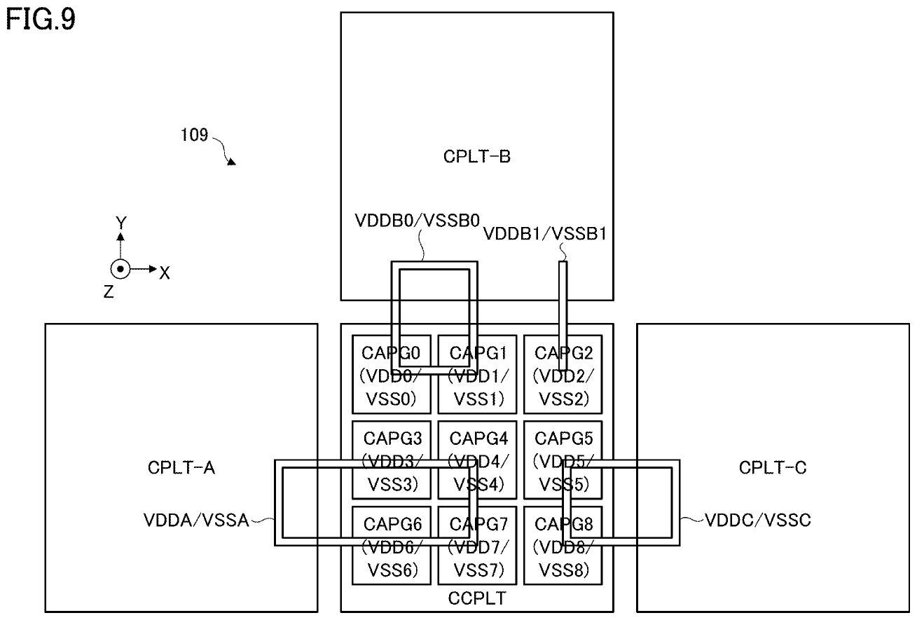

FIG. 9 illustrates an example of connecting the capacitor chiplet CCPLT of FIG. 8 to a plurality of chiplets CPLT. For example, in FIG. 9, a semiconductor package 109 on which the capacitor chiplet CCPLT of FIG. 8 is mounted has chiplets CPLT-A, CPLT-B, and CPLT-C connected to the capacitor chiplet CCPLT. The semiconductor package 109 is an example of a semiconductor product configured by a chiplet architecture.

Hereinafter, when the chiplets CPLT-A, CPLT-B, and CPLT-C are described without distinction, they are also referred to simply as chiplets CPLT. Each of the chiplets CPLT is an example of a first semiconductor device having a first circuit for performing first signal processing or a second semiconductor device having a second circuit for performing second signal processing. The capacitor chiplet CCPLT is an example of a third semiconductor device adjacent to the first semiconductor device and the second semiconductor device.

The chiplet CPLT-A is connected to the capacitor elements of the capacitor groups CAPG3, CAPG4, CAPG6, and CAPG7 (capacitor circuit blocks) via a power supply line VDDA and a ground line VSSA formed in the interposer INTP (not shown). The capacitor elements of the capacitor groups CAPG3, CAPG4, CAPG6, and CAPG7 (capacitor circuit blocks) function as decoupling capacitors for the circuits in the chiplet CPLT-A to reduce power-supply noise in the GHz band.

The power supply line VDDA is electrically connected to the power supply terminals VDD3, VDD4, VDD6, and VDD7 of the capacitor groups CAPG3, CAPG4, CAPG6, and CAPG7. The ground line VSSA is electrically connected to the ground terminals VSS3, VSS4, VSS6, and VSS7 of the capacitor groups CAPG3, CAPG4, CAPG6, and CAPG7.

The chiplet CPLT-B is connected to the capacitor elements of the capacitor groups CAPG0 and CAPG1 (capacitor circuit blocks) via the power supply line VDDB0 and the ground line VSSB0 formed in the interposer INTP (not shown). Furthermore, the chiplet CPLT-B is connected to the capacitor elements of the capacitor group CAPG2 (capacitor circuit block) via the power supply line VDDB1 and the ground line VSSB1 formed in the interposer INTP (not shown).

The capacitor elements of the capacitor groups CAPG0 and CAPG1 (capacitor circuit blocks) function as decoupling capacitors for a circuit to which the power supply line VDDB0 and the ground line VSSB0 in the chiplet CPLT-B are connected. The capacitor elements of the capacitor group CAPG2 (capacitor circuit block) function as decoupling capacitors for a circuit to which the power supply line VDDB1 and the ground line VSSB1 in the chiplet CPLT-B are connected.

The power supply line VDDB0 is electrically connected to the power supply terminals VDD0 and VDD1 of the capacitor groups CAPG0 and CAPG1. The ground line VSSB0 is electrically connected to the ground terminals VSS0 and VSS1 of the capacitor groups CAPG0 and CAPG1. The power supply line VDDB1 is electrically connected to the power supply terminal VDD2 of the capacitor group CAPG2. The ground line VSSB1 is electrically connected to the ground terminal VSS2 of the capacitor group CAPG2.

The chiplet CPLT-C is connected to the capacitor elements of the capacitor groups CAPG5 and CAPG8 (capacitor circuit block) via the power supply line VDDC and the ground line VSSC formed in the interposer INTP (not shown). The capacitor elements of the capacitor groups CAPG5 and CAPG8 (capacitor circuit blocks) function as decoupling capacitors for the circuits in the chiplet CPLT-C.

The power supply line VDDC is electrically connected to the power supply terminals VDD5 and VDD8 of the capacitor groups CAPG5 and CAPG8. The ground line VSSC is electrically connected to the ground terminals VSS5 and VSS8 of the capacitor groups CAPG5 and CAPG8.

The power supply lines VDDA, VDDB0, VDDB1, and VDDC and the ground lines VSSA, VSSB0, VSSB1 and VSSC are interconnects corresponding to the power supply line WP1 shown in FIG. 1 and the like. Hereinafter, when the power supply lines VDDA, VDDB0, VDDB1 and VDDC are described without distinction, they are also referred to simply as power supply lines VDD. When the ground lines VSSA, VSSB0, VSSB1 and VSSC are described without distinction, they are also referred to simply as ground lines VSS.

Each of the capacitor groups CAPG3, CAPG4, CAPG6, and CAPG7 and the capacitor groups CAPG0 and CAPG1 is an example of a subset of a plurality of capacitor groups CAPG (capacitor circuit blocks). The capacitor group CAPG2 and the capacitor groups CAPG5 and CAPG8 are examples of subsets of the plurality of capacitor groups CAPG (capacitor circuit blocks). The power supply line VDDA/ground line VSSA, the power supply line VDDB0/ground line VSSB0, the power supply line VDDB1/ground line VSSB1, and the power supply line VDDC/ground line VSSC are examples of subsets of the plurality of interconnects.

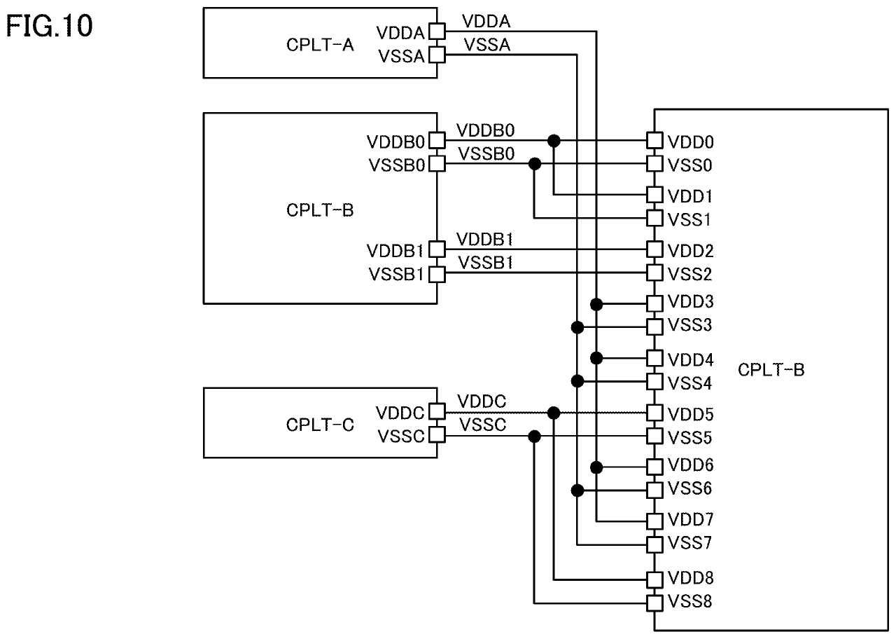

FIG. 10 illustrates an example of connection of power supply lines VDD and ground lines VSS between the capacitor chiplet CCPLT and the plurality of chiplets CPLT of FIG. 9. The connection relationship between the power supply line VDD and the ground line VSS of FIG. 10 is the same as that of FIG. 9.

As described above, in one embodiment of the capacitor chiplet, the same effect as that of the first embodiment of the semiconductor package can be obtained. For example, the capacitor chiplet CCPLT, which can be fabricated using a process older than that of the chiplets CPLT, can be arranged on the interposer INTP. Therefore, the capacitor chiplet CCPLT can be arranged near the chiplets CPLT with reduced fabrication cost, and the capacitor chiplet CCPLT can function as a decoupling capacitor for reducing power-supply noise in the GHz band.

Further, in one embodiment of the capacitor chiplet, the capacitor circuit of the capacitor chiplet CCPLT is divided into a plurality of capacitor groups CAPG (capacitor circuit blocks), and a number of the capacitor groups CAPG corresponding to the operating frequency, function, and the like of each chiplet CPLT are connected to the chiplet CPLT. As a result, a capacitor circuit of an appropriate size can be connected to each chiplet CPLT, and power-supply noise can be appropriately reduced in accordance with the operating frequency, function, and the like of each chiplet CPLT.

Further, the present invention is not limited to these embodiments, and various variations and modifications may be made without departing from the scope of the present invention.

What is claimed is

1. A semiconductor product constructed with a chiplet architecture, comprising:
an interposer including an interconnect structure;
a first semiconductor device including a first circuit configured to perform first signal processing and connected to a first surface of the interposer;
a second semiconductor device including a second circuit configured to perform second signal processing and connected to the first surface of the interposer; and
a third semiconductor device including a capacitor circuit, located adjacent to the first semiconductor device and the second semiconductor device, and connected to the first surface of the interposer,
wherein the capacitor circuit is electrically connected to the first semiconductor device and the second semiconductor device via respective interconnects of a plurality of interconnects provided in the interconnect structure.

2. The semiconductor product according to claim 1, wherein at least one of the first semiconductor device and the second semiconductor device is fabricated according to a process rule having a finer processing accuracy than a process used to fabricate the third semiconductor device.

3. The semiconductor product according to claim 1, further comprising a dummy semiconductor device connected to the first surface of the interposer and configured not to perform any signal processing.

4. The semiconductor product according to claim 1, wherein the capacitor circuit is electrically connected to a power supply terminal and a ground terminal of each of the first semiconductor device and the second semiconductor device via the interconnect structure.

5. The semiconductor product according to claim 4, wherein:
the capacitor circuit includes at least a first capacitor element and a second capacitor element;
the first capacitor element is configured to function as a decoupling capacitor for the first circuit of the first semiconductor device; and
the second capacitor element is configured to function as a decoupling capacitor for the second circuit of the second semiconductor device.

6. The semiconductor product according to claim 5, wherein the decoupling capacitor is configured to reduce power-supply noise in a GHz band.

7. The semiconductor product according to claim 1, wherein:
the capacitor circuit includes a plurality of capacitor circuit blocks each including a capacitor element;
a first subset of the plurality of capacitor circuit blocks is electrically connected to a power supply terminal and a ground terminal of the first semiconductor device via a first subset of the plurality of interconnects; and
a second subset of the plurality of capacitor circuit blocks is electrically connected to a power supply terminal and a ground terminal of the second semiconductor device via a second subset of the plurality of interconnects.

8. The semiconductor product according to claim 7, wherein each of the plurality of capacitor circuit blocks is connected to a mutually different pair of a power supply line and a ground line.

9. The semiconductor product according to claim 7, wherein:
the first subset of the plurality of capacitor circuit blocks is configured to function as a decoupling capacitor for the first circuit of the first semiconductor device; and
the second subset of the plurality of capacitor circuit blocks is configured to function as a decoupling capacitor for the second circuit of the second semiconductor device.

10. The semiconductor product according to claim 1, wherein the third semiconductor device does not have a function of independently performing active signal processing for generating an output signal in response to an input signal.

11. The semiconductor product according to claim 1, wherein the third semiconductor device is constituted of only passive elements including a capacitor element included in the capacitor circuit.

12. The semiconductor product according to claim 1, further comprising a package substrate including an external connection terminal, wherein:
a third surface of the package substrate is connected to a second surface of the interposer, which is different from the first surface of the interposer; and
the external connection terminal is provided with a fourth surface of the package substrate, which is different from the third surface of the package substrate.

13. The semiconductor product according to claim 12, wherein:
the first semiconductor device is connected to the first surface of the interposer via first bumps having a first size;
the second semiconductor device is connected to the first surface of the interposer via second bumps having the first size; and
the package substrate is connected to the second surface of the interposer via third bumps having a second size larger than the first size.

14. The semiconductor product according to claim 12, further comprising a capacitor device connected to either the third surface or the fourth surface of the package substrate, or to both the third surface and the fourth surface,
wherein each of a distance between the third semiconductor device and the first semiconductor device and a distance between the third semiconductor device and the second semiconductor device is each shorter than a distance between the capacitor device and the interposer.

15. The semiconductor product according to claim 1, wherein each of the first semiconductor device, the second semiconductor device, and the third semiconductor device is a chiplet.

16. A semiconductor device comprising
a capacitor circuit including a plurality of capacitor circuit blocks, each of the plurality of capacitor circuit blocks including a capacitor element and being connected to a mutually different pair of a power supply line and a ground line,
wherein the semiconductor device does not have a function of independently performing active signal processing for generating an output signal in response to an input signal.

17. The semiconductor device according to claim 16, wherein the semiconductor is constituted of only passive elements including the capacitor element included in the capacitor circuit.

18. The semiconductor device according to claim 16, wherein the capacitor circuit is electrically connected to a power supply terminal and a ground terminal of at least one other semiconductor device.

19. The semiconductor device according to claim 18, wherein the capacitor element included in the capacitor circuit functions as a decoupling capacitor for a circuit included in the at least one other semiconductor device.

20. The semiconductor device according to claim 16, wherein:
a first subset of the plurality of capacitor circuit blocks is electrically connected to a power supply terminal and a ground terminal of a first semiconductor device of other semiconductor devices; and
a second subset of the plurality of capacitor circuit blocks is electrically connected to a power supply terminal and a ground terminal of a second other semiconductor device different from the first semiconductor device of the other semiconductor devices.
